(19) United States
(12) Patent Application Publication
(10) Pub. No.: US 2026/0196276 A1
(43) Pub. Date: Jul. 9, 2026

(54) MEMORY DEVICE RELIABILITY VIA READ NOISE CANCELLATION

(71) Applicant: Micron Technology, Inc., Boise, ID (US)

(72) Inventors: Phong Sy Nguyen, Livermore, CA (US); Dung Viet Nguyen, San Jose, CA (US)

(21) Appl. No.: 19/013,783

(22) Filed: Jan. 8, 2025

(51) Int. Cl. G11C 16/34; G11C 16/26; G11C 29/52

(52) U.S. Cl. CPC G11C 16/3418; G11C 16/26; G11C 29/52

(57) ABSTRACT

A first batch of read operations are performed on a memory cell using a threshold read voltage and based on a first strobe. A first likelihood value that the data read from the cell corresponds to original data written to the cell is determined. A buffer storing the data read from the cell is cleared. A second batch of read operations are performed on the cell using the threshold read voltage and based on a second strobe. A second likelihood value is determined based on binary outputs of the second batch of read operations. An overall likelihood value that the data read from the cell corresponds to the original data written to the cell is determined based on the first likelihood value and the second likelihood value. The original data written to the cell is provided to a host system associated with the read operations.

### TECHNICAL FIELD

Embodiments of the disclosure relate generally to memory sub-systems, and more specifically, relate to improving memory device reliability via read noise cancellation.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system, in accordance with some embodiments of the present disclosure.

FIG. 2 illustrates a flow diagram of an example method of improving memory device reliability via read noise cancellation, in accordance with embodiments of the present disclosure.

FIG. 3 illustrates example strobe settings for performing read operations on a memory cell, in accordance with embodiments of the present disclosure.

FIG. 4 illustrates an example process for determining a likelihood that data read from a memory cell corresponds to original data written to the memory cell, in accordance with embodiments of the present disclosure.

FIG. 5 illustrates an example method for improving memory device reliability via read noise cancellation, in accordance with embodiments of the present disclosure.

FIG. 6 illustrates a block diagram of an example computer system in which embodiments of the present disclosure may operate.

### DETAILED DESCRIPTION

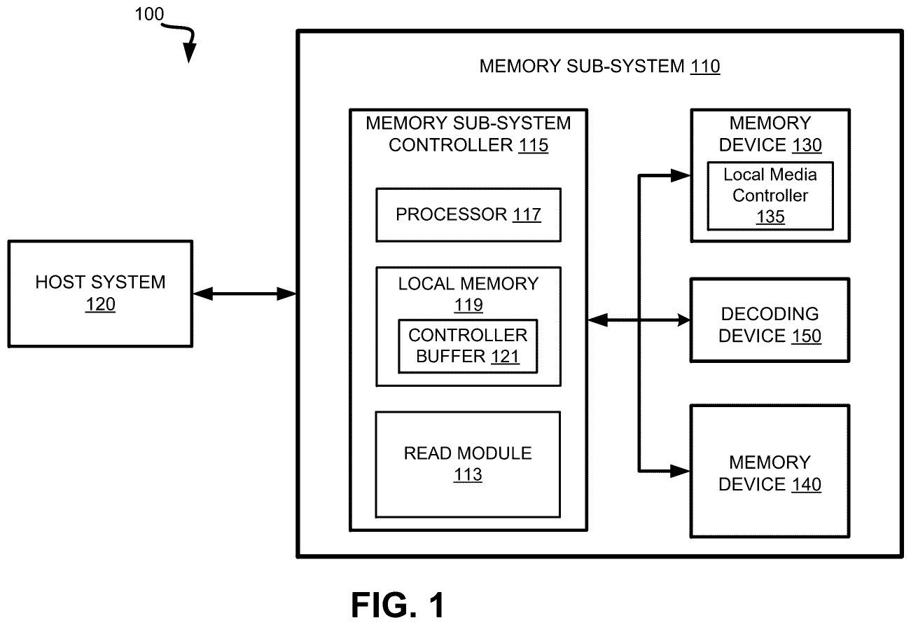

Aspects of the present disclosure are directed to improving memory device reliability via read noise cancellation. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can include of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0 ” and “1”, or combinations of such values.

A memory cell can experience different voltage levels when executing different operations and/or maintaining standard functionality. An operating voltage level of a memory cell can refer to the voltage level that is applied to maintain the standard functionality of the memory cell. Data can be written to a memory cell and/or read from a memory cell using specific voltage levels. The voltage level that is applied to write data to a memory cell (e.g., a write voltage level) can be, in some instances, different from the voltage level that is applied to read data from the memory cell (e.g., a read voltage level). In some instances, the data that is read from the memory cell can be subject to read noise (e.g., sensing noise, random telegraph noise (RTN), etc.). For example, a memory cell can experience one or more RTN traps (also referred to generally as “traps”) when an electron is trapped in the cell channel, thereby disrupting the operating voltage level of the memory cell. In some instances, a memory cell that experiences traps can also experience an increase in the operating voltage level of the memory cell, which can place the memory cell in a “filled” state. In some instances, a memory cell that experiences traps can also experience a decrease in the operating voltage level of the memory cell, which can place the memory cell in an “empty” state. When the read voltage level is applied to a memory cell that is experiencing a trap, the operating voltage level of the memory cell can fluctuate (e.g., increase or decrease). The fluctuation of the operating voltage level can impact the data that is read from the memory cell. Specifically, the data that is read from the memory cell when the memory cell experiences an increased operating voltage level can differ from the data that is read from the memory cell when the memory cell experiences a decreased operating voltage level, thereby resulting in a read error. Therefore, a memory cell can experience a read error that is caused by the noise that the memory cell experiences during a read operation.

Aspects of the present disclosure address the above and other deficiencies by providing a memory sub-system for improving memory device reliability via read noise cancellation. The memory sub-system can execute a first read operation (e.g., a hard read operation) on a memory cell. The memory sub-system can determine a likelihood value that the read data is the data that was initially written to the cell. The memory sub-system can provide the likelihood value to a decoding device (e.g., a low-density parity-check (LDPC) decoder) to determine the original data that was written to the cell. Based on determining that the decoding device successfully decoded the original data using the likelihood data, the memory sub-system can return the original data to a host device. Based on determining that the decoding device cannot decode the original data using the likelihood data, the memory sub-system can initiate the noise cancellation protocol described herein.

Specifically, the memory sub-system can execute a first batch of read operations on the memory cell, where the first batch of read operations includes a combination of hard read operations and soft read operations. The first batch of read operations can be performed using a specific read voltage level and based on a first strobe setting. A strobe setting can relay a time signal for executing each read operation of the first batch of read operations. The memory sub-system can store, in a buffer, that data that is read from the memory cell in response to the first batch of read operations. The memory sub-system can map each bit of the data that is read from the memory cell in response to each read operation of the first batch of read operations. Based on the bit mapping, the memory sub-system can determine, for each bit position, a likelihood that the data read from the memory cell corresponds to original data that was written to the memory cell. The memory sub-system can then clear the buffer of the data that is read from the memory cell in response to the first batch of read operations. In some instances, the memory sub-system can provide a likelihood value associated with each bit position to the decoding device. If the decoding device successfully determines the original data that was written to the cell based on the likelihood values, then the memory sub-system can return the original data to a host device that issued an initial read operation.

Alternatively, if the decoding device cannot determine the original data based on the likelihood values, then the memory sub-system can clear the buffer and execute a second batch of read operations that is based on the first batch of read operations. The second batch of read operations can include a subset of the hard read operations and the soft read operations of the first batch of read operations. The memory sub-system can execute the second batch of read operations on the memory cell. The second batch of read operations can be performed using the same read voltage level and based on a second strobe setting. The data that is read from the memory cell in response to the second batch of read operations can be stored in the buffer. The memory sub-system can map each bit of the data that is read from the memory cell in response to each read operation of the second batch of read operations. Based on the bit mapping, the memory sub-system can determine, for each bit position, a second likelihood value that the data read from the memory cell corresponds to the original data that was written to the memory cell. For each bit, the memory sub-system can transmit to the decoding device the second likelihood value that the data read from the cell corresponds to the original data written to the cell. In some instances, a weighted average of the first likelihood value and the second likelihood value can be used to determine an overall likelihood value that the data read from the cell corresponds to the original data. The overall likelihood value can be provided to the decoding device. In instances where the decoding device successfully determines the original data written to the cell, the memory sub-system can return the original data to the host device. However, in instances where the decoding device is unable to determine the original data written to the cell, the memory sub-system can execute additional batches of read operations.

Advantages of the present disclosure include, but are not limited to, techniques for performing read error handling based on read noise cancellation, increasing the reliability of memory devices that experience read noise during read operations, and reducing controller buffer requirements, which reduces the complexity of determining the likelihood that data read from a memory cell experiencing read noise corresponds to original data written to the memory cell.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-Dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

In some instances, the memory sub-system 110 can include a decoding device, such as decoding device 150. The decoding device 150 can be in communication with one or more components of the memory sub-system controller 115, such as the read module 113. The decoding device 150 can receive from the read module 113 one or more likelihood values (e.g., a first likelihood value, a second likelihood value, an overall likelihood value). The decoding device 150 can determine whether the original data that was written to the cell can be determined based on the received likelihood value(s). In instances where the decoding device 150 is able to decode the original data written to the cell based on the receive likelihood value(s), the original data written to the cell can be provided to a host system, such as the host system 120. Additionally or alternatively, in instances where the decoding device 150 is unable to decode the original data written to the cell based on the received likelihood value(s), an error handling procedure described herein can be performed.

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. The local memory 119 can also include controller buffer 121 for, for example, storing data that is read from a memory cell as a result of each read operation. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a read module 113 that can perform multiple batches of read operations on a memory cell that may experience read noise. For each bit of the data read from the memory cell in response to each read operation of a batch of read operations, the read module 113 can store the read data in local memory 119. Specifically, the read module 113 can store the read data in controller buffer 121. Based on performing a first read operation, the read module 113 can determine a first likelihood value that the data read from a bit position corresponds to original data that was written to the bit position. For each additional read operation that is performed on the cell (e.g., a second read operation), the read module 113 can determine a second likelihood value that the data bit value read from a cell corresponds to the original data bit value that was written to the cell. The read module 113 can communicate with a decoding device to determine, based on the first and second likelihood values, the original data that was written to each cell. In some embodiments, the read module 113 is part of the host system 120, an application, or an operating system. In other embodiments, local media controller 135 includes at least a portion of read module 113 and is configured to perform the functionality described herein.

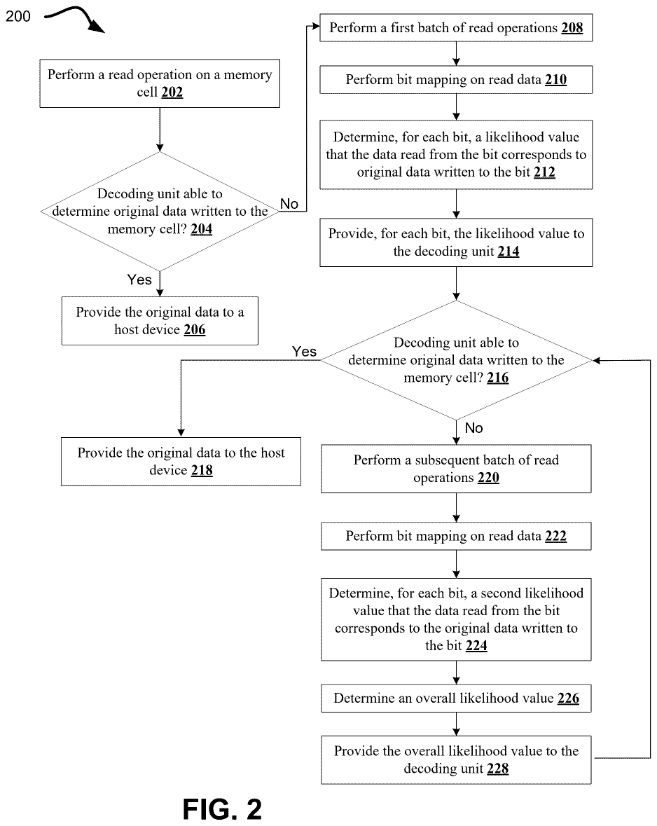

FIG. 2 illustrates a flow diagram of an example method 200 for improving memory device reliability via read noise cancellation, in accordance with some embodiments of the present disclosure. The method 200 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 200 is performed by the read module 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 202, the processing logic (e.g., the read module 113) can perform a read operation on a memory cell of a memory device, such as memory device 130, which may be a NAND memory device, for example. The processing logic can determine, for each bit of the data read from the memory cell, a likelihood value (e.g., a first likelihood value) that the data read from each position corresponds to the data that was originally written to each bit position. The processing logic can provide the determined likelihood values to a decoding device (e.g., decoding device 150) to determine the original data that was written to the cell.

At operation 204, the processing logic can determine whether the decoding device successfully determined the original data based on, for example, the received likelihood values. If the processing logic determines that the decoding device successfully decoded the received likelihood values to determine the original data, then, at operation 206, the processing logic can provide the original data to a host system associated with the read operation, such as host system 120.

If the processing logic determines that the decoding device could not decode the received likelihood values to determine the original data, however, then the processing logic can initiate read error handling. Specifically, at operation 208, the processing logic can determine a first batch of read operations to be performed on the same memory cell (i.e., the memory cell that was read at operation 202). The first batch of read operations can include a combination of one or more hard read operations and soft read operations. A hard read operation can correspond to a first read operation, of a batch of read operations, that is performed on a cell. A soft read operation can correspond to a subsequent read operation, of the same batch of read operations as the hard read operation, that is performed on the cell after the hard read operation, for example. In some instances, the first batch of read operations can include an initial read operation, such as the read operation performed at operation 202. A hard read operation of the first batch of read operations can be performed using a specific read voltage level and based on a first strobe setting. The first strobe setting can indicate a time for performing the read operation. One or more soft read operations can be performed using the same read voltage level as the hard read operation. However, the one or more soft read operations can be performed based on a second strobe setting that, in some instances, can be different from the first strobe setting.

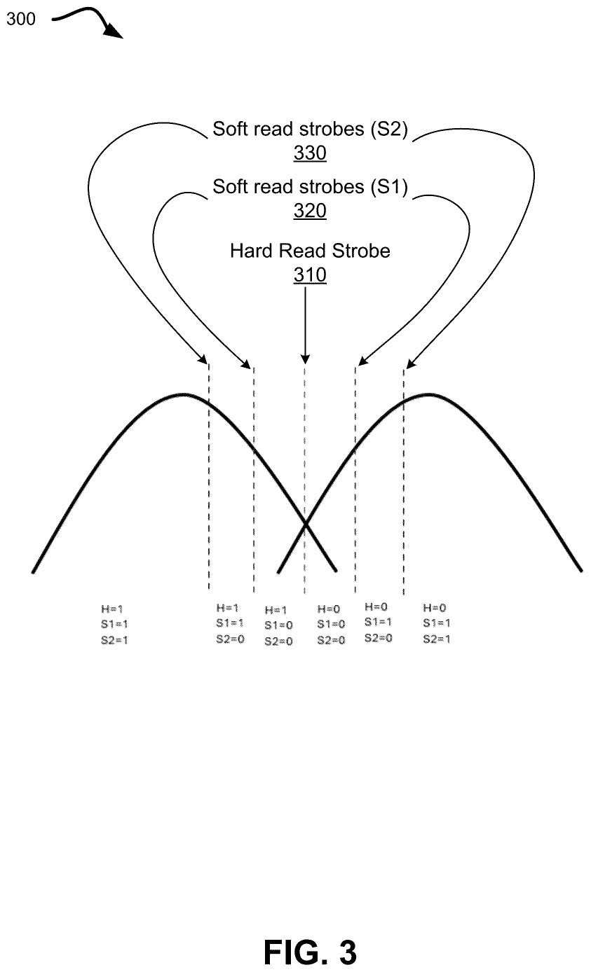

FIG. 3 illustrates example strobe settings for performing read operations on a memory cell. Example waveform 300 illustrates an operating voltage level of an example memory cell. A read voltage level can be applied to the memory cell to perform a read operation on the memory cell. The read voltage level can be applied to the memory cell based on a time signal indicated by a strobe setting. When the memory cell experiences read noise and/or traps, applying the read voltage level to the memory cell at different times (e.g., based on different strobe settings) can result in different data being read from the same memory cell. For example, as illustrated in FIG. 3, one hard read and two soft read operations can be performed on the memory cell. The hard read is performed based on hard read strobe 310, a first soft read is performed based on soft read strobes (S1) 320, and a second soft read is performed based on soft read strobes (S2) 330. In some instances, each of hard read strobe 310, soft read strobes 320, and soft read strobes 330 can correspond to different strobe settings. While three read operations are illustrated, the processing logic can perform more or fewer read operations on a memory cell. Each of the hard and soft read operations can be performed on the memory cell using the same read voltage level, which can be applied to the memory cell at different times. Each read operation can output binary data that is read from the memory cell at different times.

As described in detail below, the binary data that is output as a result of each read operation can be used to determine whether the data read from the memory cell corresponds to (e.g., matches) original data that was written to the memory cell. In some instances, the processing logic can analyze each bit of the binary data that is output as a result of each read operation to determine whether the binary data corresponds to the original data.

Returning to FIG. 2, at operation 210, the processing logic can perform bitmapping on the binary data that is output as a result of each read operation of the first batch of read operations. In some instances, the processing logic can use one or more processing devices to perform the bitmapping and determine the likelihood that the binary data read from the memory cell is the original data written to the memory cell. In some instances, the likelihood that the binary data read from the memory cell is the original data written to the memory cell is determined based on, for example, a log-likelihood ratio (LLR) associated with each bit of the binary data that is read from the memory cell. In some instances, the one or more processing devices can include an LLR generator (referred to as “LLR Gen”).

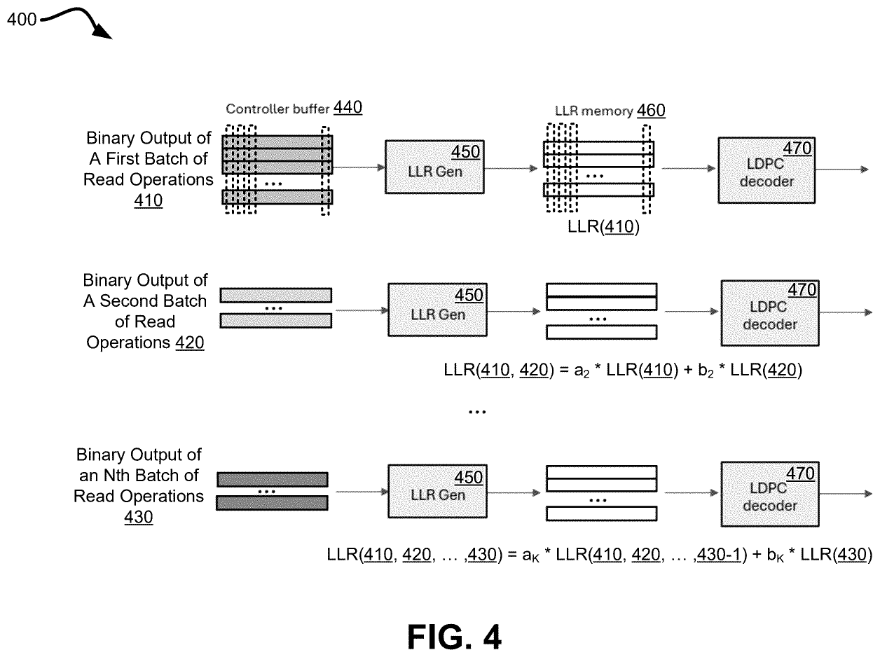

As described above, each read operation can return a string of binary data. The binary data that is returned as a result of each read operation can be stored in a buffer, such as controller buffer 121 of the memory sub-system 110. The binary data that is stored in the controller buffer as a result of each batch of read operations can be used to determine the likelihood that the data read from the memory cell as a result of each read operation is the original data that was written to the memory cell. FIG. 4 illustrates an example process for determining a likelihood that data read from a memory cell corresponds to original data written to the memory cell. The binary data that is returned as a result of the first batch of read operations (e.g., binary output of a first batch of read operations 410, generally referred to as “binary output 410”) can be stored in controller buffer 440. The binary output 410 can include the binary outputs of a hard read operation and one or more soft read operations. The processing logic can use LLR Gen 450 to perform bitmapping. Specifically, LLR Gen 450 can compare each bit in each bit position across binary output 410. In some instances, the portion of the binary data 410 that is returned as a result of a hard read operation can be the original data that was written to the memory cell. LLR Gen 450 can compare the remainder of the binary output 410 (e.g., the portions of the binary data 410 that are returned as a result of the soft read operations) to the binary data that is output as a result of the hard read operation. If the binary data in a bit that is output as a result of a soft read operation matches the binary data in a bit in the same bit position that is output as a result of the hard read operation, LLR Gen 450 can determine that the binary data in the bit associated with the soft read operation is likely the binary data that was originally written to the bit. However, if the binary data in the bit position associated with the first soft read operation is different from the binary data in the same bit position in the binary data associated with the hard read operation, then the LLR Gen 450 can determine that it is less likely that the binary data in the bit position associated with the first soft read operation is the binary data that was originally written to the bit.

Returning to FIG. 2, at operation 212, the processing logic can determine, for each bit of the binary data that is output as a result of the batch of read operations (e.g., binary data 410), a log-likelihood ratio (LLR) value indicating the likelihood that the binary data in each bit position corresponds to the binary data that was originally written to each bit position. In some instances, the processing logic can use LLR Gen 450 to determine the LLR value associated with each bit position of the binary output data. The LLR Gen 450 can determine the LLR value for each bit position by determining the log of a ratio of a probability that a binary output of the bit is a binary “0 ” given the data read from the memory cell and a probability that a binary output of the bit is a binary “1” given the data read from the memory cell. The LLR values can be stored in LLR memory 460. Referring to FIG. 4, in some instances, the LLR Gen 450 can determine an LLR value (e.g., a first likelihood value) that indicates the likelihood that the binary data returned as a result of the first batch of read operations (e.g., binary data 410) corresponds to the original data that was written to the memory cell. For example, the LLR value that indicates the likelihood that the binary data 410 corresponds to the original data written to the memory cell can be denoted as LLR(410).

At operation 214, the processing logic can provide the LLR value of the binary data that is output as a result of the batch of read operations (e.g., LLR(410)) to a decoding device, such as LDPC decoder 470. The decoding device can analyze the received data to determine whether the original data written to the cell can be decoded.

At operation 216, the processing logic can determine whether the decoding device successfully decoded the received data (e.g., whether the decoding device successfully output the original data that was written to the cell). If, at operation 216, the processing logic determines that the decoding device successfully determined the original data, then, at operation 218, the processing logic can provide the original data to the host system associated with the read operation, such as host system 120. The processing logic can clear the controller buffer 440 after each batch of read operations is analyzed.

However, if, at operation 216, the processing logic determines that the decoding device could not determine the original data, then, at operation 220, the processing logic can perform a subsequent batch of read operations, such as a second batch of read operations. The second batch of read operations can include a subset of read operations of the first batch of read operations. For example, the second batch of read operations can include a combination of the hard read operation(s) and the soft read operation(s) of the first batch of read operations. The second batch of read operations can be executed on the same memory cell as the first batch of read operations. The second batch of read operations can be performed using the same read voltage level as the first batch of read operations. However, the second batch of read operations can be performed based on a different time signal than the time signal that is used to perform the first batch of read operations (e.g., based on a second strobe setting). Each read operation of the second batch of read operations can output binary data that was read from the memory cell, collectively referred to herein as binary output of a second batch of read operations 420 (generally referred to as “binary output 420”). Binary output 420 can be stored in controller buffer 440.

At operation 222, the processing logic can perform bitmapping on the binary data that is output as a result of the subsequent batch of read operations (e.g., binary output 420). In some instances, the processing logic can use LLR Gen 450 to perform the bitmapping. LLR Gen 450 can compare the binary data in each bit position of binary output 420 to the binary data in the corresponding bit position of binary output 410 to determine a likelihood that binary output 410 corresponds to the original data that was written to the memory cell.

At operation 224, the processing logic can determine, for each bit, a second likelihood value (e.g., a second LLR value) that the binary data read from each bit position corresponds to the original data that was written to each bit position. In some instances, the processing logic can use LLR Gen 450 to determine a second LLR value associated with each bit position of the binary output data that is output as a result of the subsequent batch of read operations. In some instances, the processing logic can use the LLR Gen 450 to the determine the second LLR value of each bit position of, for example, binary output 420. The LLR Gen 450 can determine the second LLR value for each bit position by determining the log of a ratio of a probability that a binary output of the bit is a binary “0 ” given the data read from the memory cell and a probability that a binary output of the bit is a binary “1” given the data read from the memory cell. Referring to FIG. 4, in some instances, the LLR Gen 450 can determine an LLR value (e.g., the second likelihood value) that the binary data returned as a result of the subsequent batch of read operations (e.g., binary data 420) corresponds to the original data that was written to the memory cell. For example, the second likelihood value that the binary data 420 corresponds to the original data written to the memory cell can be denoted as LLR(420). The LLR values can be stored in LLR memory 460.

In some instances, based on determining that the second likelihood value indicates that the binary data that is output as a result of the first batch of read operations is different from the original data that was written to the cell, the processing logic can initiate an error correction protocol on the cell. Specifically, the processing logic can use error correction code (ECC) associated with the cell to, for example, determine the original data that was written to the cell. In some instances, the processing logic can provide the original data that was written to the cell to the host system associated with the read operations (e.g., the host system 120).

At operation 226, the processing logic can determine an overall log-likelihood ratio (LLR) value (e.g., using the LLR Gen 450). The overall likelihood value can indicate the likelihood that the binary outputs of each batch of read operations (e.g., binary output 410 and binary output 420) correspond to the original data that was written to the memory cell. In instances where the processing logic executes subsequent batches of read operations, the overall likelihood value can be based on the LLR values that correspond to each batch of read operations. Specifically, the overall LLR value can be based on a sum of weighted LLR values. For example, an overall LLR value of binary output 410 and binary output 420 can be the sum of a weighted value of LLR(410) and a weighted value of LLR(420).

At operation 228, the processing logic can provide the overall likelihood value to the decoding device, such as LDPC decoder 470. The overall likelihood value can be based on a combination of the first likelihood value (e.g., LLR(410)) and the second likelihood value (e.g., LLR(420)). The processing logic can return to operation 216. Specifically, the processing logic can determine whether the decoding device successfully decoded the received data (e.g., whether the decoding device successfully output the original data that was written to the cell).

If the processing logic determines that the decoding device successfully determined the original data, then the processing logic can provide the original data to the host system associated with the read operation, such as host system 120. However, if the processing logic determines that the decoding device could not determine the original data, then the processing logic can clear the controller buffer 440 and perform a subsequent batch of read operations. For example, referring to FIG. 4, the processing logic can perform an N^{th} batch of read operations, which can return the binary output of an N^{th} batch of read operations 430 (generally referred to as “binary output 430”). For each additional batch of read operations that is performed on the memory cell, the processing logic can determine an N^{th} log-likelihood ratio (LLR) value (e.g., an N^{th} likelihood value) that the binary data that is output as a result of each additional batch of read operations corresponds to the binary data that was originally written to the memory cell. The processing logic can also determine an updated overall log-likelihood ratio (LLR) value indicating the likelihood that the binary data that is output as a result of each additional batch of read operations corresponds to the original data that was written to the memory cell based on a sum of weighted LLR values.

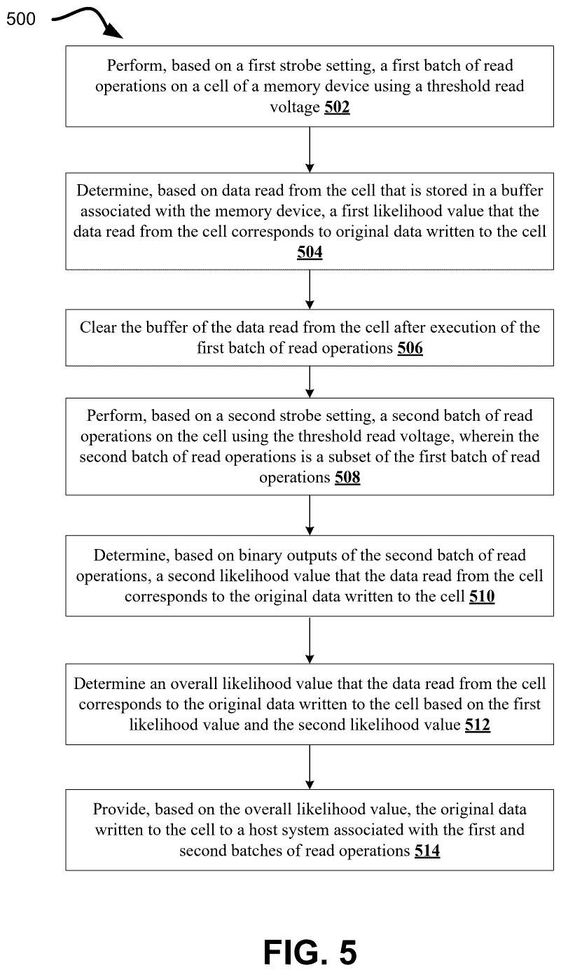

FIG. 5 illustrates a flow diagram of an example method 500 for improving memory device reliability via read noise cancellation, in accordance with some embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the read module 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 502, the processing logic can perform, based on a first strobe setting, a first batch of read operations on a cell of a memory device, such as memory device 130, using a threshold read voltage. The first batch of read operations can include a hard read and one or more soft read operations.

At operation 504, the processing logic can determine, based on data read from the cell that is stored in a buffer associated with the memory device, a first likelihood value that the data read from the cell corresponds to original data written to the cell. The processing logic can map binary data in each bit position of the data read from the cell in response to each read operation of the first batch of read operations. A first binary output of a bit position of the data read from the cell can indicate that the data read from the cell matches the original data written to the bit position. A second binary output of the bit position of the data read from the cell can indicate that the data read from the cell is different from the original data written to the bit position.

In some instances, determining the first likelihood value can include determining, for each bit position of the data read from the cell, a log of a ratio of a probability that a binary output of the bit position is the second binary output given the data read from the cell and a probability that a binary output of the bit position is the first binary output given the data read from the cell.

At operation 506, the processing logic can clear the buffer of the data read from the cell after execution of the first batch of read operations.

At operation 508, the processing logic can perform, based on a second strobe setting, a second batch of read operations on the cell using the threshold read voltage. The second batch of read operations can be a subset of the first batch of read operations. In some instances, the second batch of read operations can include a hard read operation that is performed based on the second strobe setting and one or more soft read operations that are performed based on the second strobe setting.

At operation 510, the processing logic can determine, based on binary outputs of the second batch of read operations, a second likelihood value that the data read from the cell corresponds to the original data written to the cell. In some instances, the second likelihood value can be a binary value.

At operation 512, the processing logic can determine an overall likelihood value that the data read from the cell corresponds to the original data written to the cell based on the first likelihood value and the second likelihood value. The overall likelihood value that the data read from the cell corresponds to the original data written to the cell can be based on a sum of a weighted value of the first likelihood value that the data read from the cell corresponds to the original data written to the cell and a weighted second likelihood value that the data read from the cell corresponds to the original data written to the cell.

At operation 514, the processing logic can provide, based on the overall likelihood value, the original data written to the cell to a host system associated with the first and second batches of read operations (e.g., the host system 120 of FIG. 1). To determine the original data written to the cell, the processing logic can provide the overall likelihood value to a decoding device that is coupled to the processing logic. The processing logic can provide the data read from the cell to a host device based on determining that the decoding device decodes the original data written to the cell using the overall likelihood value. In some instances, the processing logic can initiate an error correction protocol using error correction code (ECC) associated with the cell based on determining that the decoding device cannot decode the original data written to the cell using the overall likelihood value.

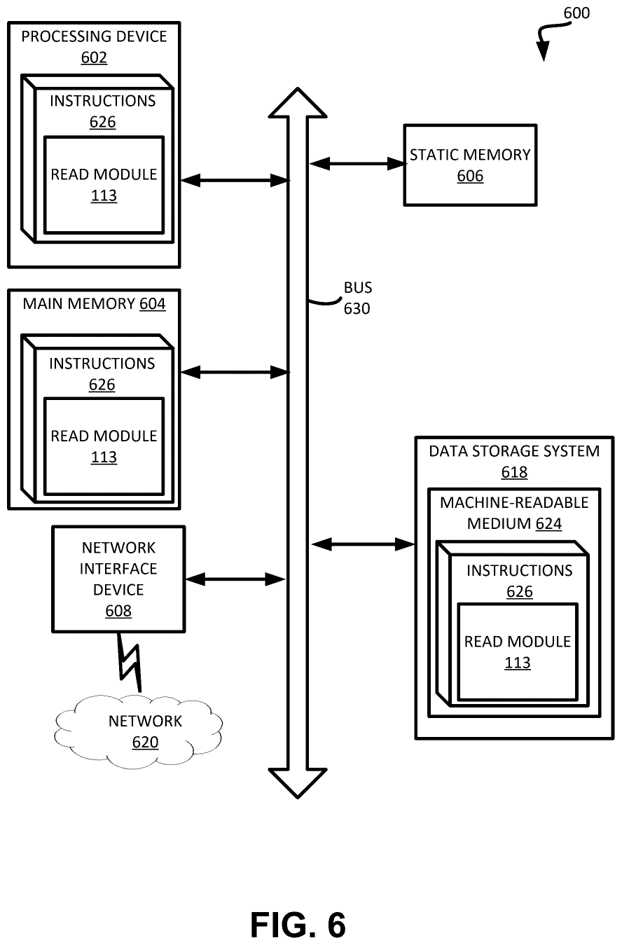

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the read module 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or RDRAM, etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIG. 1.

In one embodiment, the instructions 626 include instructions to implement functionality corresponding to a read module (e.g., the read module 113 of FIG. 1). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device operatively coupled to the memory device and configured to perform operations comprising:
performing, based on a first strobe setting, a first batch of read operations on a cell of the memory device using a threshold read voltage;
determining, based on data read from the cell that is stored in a buffer associated with the memory device, a first likelihood value that the data read from the cell corresponds to original data written to the cell;
clearing, from the buffer, the data read from the cell after execution of the first batch of read operations;
performing, based on a second strobe setting, a second batch of read operations on the cell using the threshold read voltage, wherein the second batch of read operations is a subset of the first batch of read operations;
determining, based on binary outputs of the second batch of read operations, a second likelihood value that the data read from the cell corresponds to the original data written to the cell;
determining an overall likelihood value that the data read from the cell corresponds to the original data written to the cell based on the first likelihood value and the second likelihood value; and
providing, based on the overall likelihood value, the original data written to the cell to a host system associated with the first and second batches of read operations.

2. The system of claim 1, wherein the overall likelihood value that the data read from the cell corresponds to the original data written to the cell is further based on a sum of a weighted value of the first likelihood value that the data read from the cell corresponds to the original data written to the cell and a weighted value of the second likelihood value that the data read from the cell corresponds to the original data written to the cell.

3. The system of claim 1, wherein the first batch of read operations comprises:
a hard read operation that is performed based on the first strobe setting; and
one or more soft read operations that are performed based on the first strobe setting.

4. The system of claim 1, wherein determining the first likelihood value that the data read from the cell corresponds to the original data written to the cell further causes the processing device to perform operations comprising:
mapping binary data in each bit position of the data read from the cell in response to each read operation of the first batch of read operations.

5. The system of claim 1, wherein:
a first binary output of a bit position of the data read from the cell indicates that data read from the cell matches the original data written to the bit position; and
a second binary output of the bit position of the data read from the cell indicates that the data read from the cell is different from the original data written to the bit position.

6. The system of claim 5, wherein determining the first likelihood value that the data read from the cell corresponds to the original data written to the cell further causes the processing device to perform operations comprising:
determining, for each bit position of the data read from the cell, a log of a ratio of a probability that a binary output of the bit position is the second binary output given the data read from the cell and a probability that a binary output of the bit position is the first binary output given the data read from the cell.

7. The system of claim 1, wherein the processing device is further configured to perform operations comprising:
providing the data read from the cell to a host device based on determining that a decoding device coupled to the processing device decodes the original data written to the cell using the overall likelihood value.

8. The system of claim 1, wherein the processing device is further configured to perform operations comprising:
initiating an error correction protocol using error correction code (ECC) associated with the cell based on determining that a decoding device coupled to the processing device cannot decode the original data written to the cell using the overall likelihood value.

9. The system of claim 1, wherein the second likelihood value comprises a binary value.

10. The system of claim 1, wherein the second batch of read operations comprises:
a hard read operation that is performed based on the second strobe setting; and
one or more soft read operations that are performed based on the second strobe setting.

11. A method comprising:
performing, based on a first strobe setting, a first batch of read operations on a cell of a memory device using a threshold read voltage;
determining, based on data read from the cell that is stored in a buffer associated with the memory device, a first likelihood value that the data read from the cell corresponds to original data written to the cell;
clearing, from the buffer, the data read from the cell after execution of the first batch of read operations;
performing, based on a second strobe setting, a second batch of read operations on the cell using the threshold read voltage, wherein the second batch of read operations is a subset of the first batch of read operations;
determining, based on binary outputs of the second batch of read operations, a second likelihood value that the data read from the cell corresponds to the original data written to the cell;
determining an overall likelihood value that the data read from the cell corresponds to the original data written to the cell based on the first likelihood value and the second likelihood value; and
providing, based on the overall likelihood value, the original data written to the cell to a host system associated with the first and second batches of read operations.

12. The method of claim 11, wherein determining the first likelihood that the data read from the cell corresponds to the original data written to the cell further comprises:
mapping binary data in each bit position of the data read from the cell in response to each read operation of the first batch of read operations.

13. The method of claim 11, wherein the second likelihood value comprises a binary value.

14. The method of claim 11, further comprising:
providing the data read from the cell to a host device based on determining that a decoding device coupled to the processing device decodes the original data written to the cell using the overall likelihood value.

15. The method of claim 11, further comprising:
initiating an error correction protocol using error correction code (ECC) associated with the cell based on determining that a decoding device coupled to the processing device cannot decode the original data written to the cell using the overall likelihood value.

16. The method of claim 11, wherein the first batch of read operations comprises:
a hard read operation that is performed based on the first strobe setting; and
one or more soft read operations that are performed based on the first strobe setting.

17. The method of claim 11, wherein the second batch of read operations comprises:
a hard read operation that is performed based on the second strobe setting; and
one or more soft read operations that are performed based on the second strobe setting.

18. A non-transitory computer-readable storage medium comprising instructions that, when executed by a processing device, cause the processing device to perform operations comprising:
performing, based on a first strobe setting, a first batch of read operations on a cell of a memory device using a threshold read voltage;
determining, based on data read from the cell that is stored in a buffer associated with the memory device, a first likelihood value that the data read from the cell corresponds to original data written to the cell;
clearing, from the buffer, the data read from the cell after execution of the first batch of read operations;
performing, based on a second strobe setting, a second batch of read operations on the cell using the threshold read voltage, wherein the second batch of read operations is a subset of the first batch of read operations;
determining, based on binary outputs of the second batch of read operations, a second likelihood value that the data read from the cell corresponds to the original data written to the cell;
determining an overall likelihood value that the data read from the cell corresponds to the original data written to the cell based on the first likelihood value and the second likelihood value; and
providing, based on the overall likelihood value, the original data written to the cell to a host system associated with the first and second batches of read operations.

19. The non-transitory computer-readable storage medium of claim 18, wherein the processing device is further configured to perform operations comprising:
providing the data read from the cell to a host device based on determining that a decoding device coupled to the processing device decodes the original data written to the cell using the overall likelihood value.

20. The non-transitory computer-readable storage medium of claim 18, wherein the processing device is further configured to perform operations comprising:
initiating an error correction protocol using error correction code (ECC) associated with the cell based on determining that a decoding device coupled to the processing device cannot decode the original data written to the cell using the overall likelihood value.
